(19) United States
(12) Patent Application Publication
(10) Pub. No.: US 2013/0196112 A1
(43) Pub. Date: Aug. 1, 2013

(54) OXIDE MESOSTRUCTURED FILM AND METHOD FOR MANUFACTURING THE SAME

(71) Applicant: CANON KABUSHIKI KAISHA, Tokyo (JP)

(72) Inventor: Wataru Kubo, Inagi-shi (JP)

(73) Assignee: CANON KABUSHIKI KAISHA, Tokyo (JP)

(21) Appl. No.: 13/750,902

(22) Filed: Jan. 25, 2013

(30) Foreign Application Priority Data
Jan. 30, 2012 (JP) 2012-016897

(51) Int. Cl. B82B 1/00; C23C 16/04

(52) U.S. Cl. CPC B82B 1/001; C23C 16/04
USPC 428/116; 427/255.28

(57) ABSTRACT

An oxide mesostructured film has a structure in which the orientation direction of cylindrical structures is a given direction throughout in the film plane, at least one peak appears in an angle region corresponding to a plane spacing of 8 nm or more, the number of atoms (X) of silicon to which an alkyl group having 8 or more carbon atoms is bonded to the number of atoms (Y) of silicon or metallic elements among elements constituting oxides of the oxide mesostructured film is 0.1 or more and 0.5 or lower in terms of the atomic number ratio (X/Y).

### BACKGROUND OF THE INVENTION

1. Field of the Invention

The present invention relates to an oxide mesostructured film and a method for manufacturing the same.

2. Description of the Related Art

Mesoporous materials have been expected to be variously applied due to a large specific surface area, a low dielectric constant, a low refractive index, and a highly regular structure thereof. A silica mesoporous film is important in terms of electrically and optically applying the excellent properties of the mesoporous materials. Particularly, since a mesoporous film in which the orientation in the film plane of a mesoporous film having a two-dimensional hexagonal structure prepared on a substrate is controlled has a structure in which tube-like oxide walls are aligned in the film, an application of the film as a host which gives anisotropy to a compound introduced into pores has been reported.

Some techniques for controlling the in-plane orientation of the mesoporous film have been reported so far. Particularly, when a polymer film subjected to rubbing treatment, which is widely used as a liquid crystal orientation technique for displays, is utilized as a substrate, the mesoporous film to be formed shows high orientation. The mechanism such that the polyimide film subjected to rubbing treatment gives orientation to mesoporous silica is briefly described as follows. Surfactant molecules containing an alkyl group serving as a template of mesoporous silica are oriented in a rubbing direction due to the chemical interaction with an alkyl group in polyimide molecules which are oriented by rubbing treatment. Then, a two-dimensional hexagonal structure containing cylindrical micelles is formed with the oriented surfactant molecules as the starting point. As a result, an oxide mesostructured film of the two-dimensional hexagonal structure in which cylinders are oriented in a direction perpendicular to the rubbing direction is formed. Herein, one in which the template molecules are removed from the oxide mesostructured film, and hollow fine pores are formed is referred to as a mesoporous film. Particularly, one in which the directions of the fine pores are controlled in one direction in the film plane is referred to as an oriented mesoporous film.

In order to use the mesoporous silica as a vessel of various guest molecules, e.g., biomechanical materials or light emission materials, an examination of increasing the fine pore diameter and the structure period thereof has been vigorously performed. As a method for preparing an oxide mesostructured film having a large structure period, PCT Japanese Translation Patent Publication No. 2003-531083 discloses forming an oxide mesostructured film using, as a template, an amphiphilic block copolymer which is known to give a mesostructure of a large structure period as compared with a surfactant containing an alkyl group.

Japanese Patent Laid-Open No. 2001-145831 discloses the preparation of an oxide mesostructured film by using a polyimide coated substrate subjected to rubbing treatment as an anisotropic substrate, and then achieving orientation due to the chemical interaction of the substrate and an alkyl group of a surfactant.

However, when an oxide mesostructured film is prepared using an amphiphilic block copolymer as a template and using a polyimide coated substance subjected to rubbing treatment as a substrate, it has not been easy to obtain an oriented oxide mesostructured film. This is considered that an amphiphilic block copolymer has weak interaction with the oriented molecules on the substrate as compared with a surfactant having an alkyl chain as a hydrophobic group and a large structure period is obtained, but it is difficult to form orientation.

### SUMMARY OF THE INVENTION

The present invention provides an oxide mesostructure a structure period having a good orientation on a substrate and a method for manufacturing the same.

An oxide mesostructured film which solves the above-described problems is an oxide mesostructured film having a structure in which cylindrical structures are packed in the shape of a honeycomb, in which the orientation direction of the cylindrical structures is a given direction throughout in the film plane, at least one peak appears in an angle region corresponding to a plane spacing of 8 nm or more in the X-ray diffraction measurement in the Bragg-Brentano geometry, and the number of atoms (X) of silicon to which an alkyl group having 8 or more carbon atoms is bonded to the number of atoms (Y) of silicon or metallic elements among elements constituting oxides of the oxide mesostructured film is 0.1 or more and 0.5 or lower in terms of the atomic number ratio (X/Y).

An oxide mesostructured film which solves the above-described problems is an oxide mesostructured film having a structure in which cylindrical structures are packed in the shape of a honeycomb, in which the orientation direction of the cylindrical structures is a given direction throughout in the film plane, at least one peak appears in an angle region corresponding to a plane spacing of 8 nm or more in the X-ray diffraction measurement in the Bragg-Brentano geometry, and the number of atoms (X″) of silicon to which an alkyl group having 8 or more carbon atoms is bonded to the number of atoms (Y″) of silicon of silica constituting the oxide mesostructured film is 0.1 or more and 0.5 or lower in terms of the atomic number ratio (X″/Y″).

An oxide mesostructured film which solves the above-described problems is an oxide mesostructured film having a structure in which cylindrical structures are packed in the shape of a honeycomb, in which the orientation direction of the cylindrical structures is a given direction throughout in the film plane, the number of atoms (X) of silicon to which an alkyl group having 8 or more carbon atoms is bonded to the number of atoms (Y) of silicon or metallic elements among elements constituting oxides of the oxide mesostructured film is 0.1 or more and 0.5 or lower in terms of the atomic number ratio (X/Y), and the number of atoms (Z) of silicon to which carbon, to which a hydroxyl group is directly bonded, is bonded to the number of atoms (Y) is 0.02 or more and 0.2 or lower in terms of the atomic number ratio (Z/Y).

A method for manufacturing the oxide mesostructured film which solves the above-described problems includes a process for performing a polycondensation reaction of an oxide precursor containing a silicon compound 1 represented by the following general formula (1) in the presence of a surfactant on a substrate having anisotropy in the orientation direction of molecules in the substrate plane to form an oxide mesostructured film having an oriented ordered structure in the film plane, in which the content of silicon (X′) of the silicon compound 1 to the number of atoms (Y′) of silicon or metallic elements among elements constituting the oxide precursor containing the silicon compound 1 is 0.1 or more and 0.5 or lower in terms of the number ratio of atoms (X′/Y′).

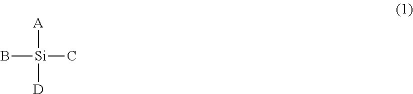

In the formula above, A represents an alkyl group having 8 or more carbon atoms. B, C, and D represent an alkoxy group, chlorine, bromine, or iodine. B, C, and D may be the same or may be different from each other.

Further features of the present invention will become apparent from the following description of exemplary embodiments with reference to the attached drawings.

### BRIEF DESCRIPTION OF THE DRAWINGS

FIGS. 1A and 1B are views explaining the interaction between an oxide mesostructured film and a substrate with anisotropic molecular orientation according to a suitable embodiment of the invention.

FIG. 2 is a view illustrating a half width value of the in-plane XRD rocking curve to the value of the atomic number ratio x of a silicon compound 1 of an oxide mesostructured film prepared in Example 2.

FIG. 3 is a view illustrating the in-plane rocking curve profile of the oxide mesostructured film prepared in Example 2.

FIGS. 4A and 4B are views illustrating a two-dimensional XRD pattern when the atomic number ratio x of the silicon compound 1 of the oxide mesostructured film prepared in Example 2 is 0.3.

FIG. 5 is a view illustrating the in-plane rocking curve profile when the atomic number ratio z of a silicon compound 2 of an oxide mesostructured film prepared in Example 4 is 0.1.

FIGS. 6A and 6B are views illustrating a two-dimensional XRD pattern when the atomic number ratio z of the silicon compound 2 of the oxide mesostructured film prepared in Example 4 is 0.1.

FIG. 7 is a view illustrating a cross-sectional SEM image when the atomic number ratio z of the silicon compound 2 of the oxide mesostructured film prepared in Example 4 is 0.1.

### DESCRIPTION OF THE EMBODIMENTS

Hereinafter, embodiments of the invention are described in detail.

First, the terms used for describing the embodiments of the invention, (1) oxide, (2) oxide mesostructured film, and (3) surfactant are individually described.

### (1) Oxide

In the invention, an oxide has a concept which includes one containing an inorganic oxide and an organic substance in or outside the skeleton of the inorganic oxide. As an example of the inorganic oxide, silicon oxide, tin oxide, zirconium oxide, titanium oxide, niobium oxide, tantalum oxide, aluminum oxide, tungsten oxide, hafnium oxide, and zinc oxide can be mentioned. Among the above, silicon oxide, tin oxide, zirconium oxide, titanium oxide, and hafnium oxide are suitable, and silicon oxide is the most suitable. Mentioned as one containing an organic substance in the skeleton of an inorganic oxide is one in which atoms other than oxygen constituting the inorganic oxide are bonded to organic molecules as in the silicon described above, for example. Mentioned as an example of the organic molecules are aromatic compounds, such as a phenyl group, and aliphatic compounds, such as a methyl group and a methylene group. The oxide is formed from an oxide precursor.

As an example of the oxide precursor, alkoxides and chlorides of silicon and metallic elements are mentioned. Mentioned as a further specific example are alkoxides and chlorides of Si, Sn, Zr, Ti, Nb, Ta, Al, W, Hf, and Zn. Mentioned as an example of the alkoxide are methoxide, ethoxide, propoxide, or one in which the alkoxy group thereof is partially substituted with an alkyl group.

### (2) Oxide Mesostructured Film

In recent years, a study on a mesostructure material which is formed using an aggregate of a surfactant as a template has been vigorously performed, and it has become possible to produce an oxide mesostructured film having a high structural regularity of a nanometer-scale size. In the invention, an oxide mesostructured film has a concept which includes the following films.

### (A) Oxide Mesostructured Film

### (B) Mesoporous Film

These films are described below. Porous materials are classified according to the pore diameter, and porous materials having a pore diameter of 2 to 50 nm are classified into mesoporous materials.

### (A) Oxide Mesostructured Film

A film of a material in which a molecular aggregate mainly serves as a template, the structure of the aggregate is fixed by a wall portion mainly containing an oxide, and the diameter of the template is 2 to 50 nm is mentioned. Mentioned as an example of the material forming the molecular aggregate is a surfactant. In the template, water, an organic solvent, salt, or the like may be contained as required or as a result of materials and processes to be used. Mentioned as an example of the organic solvent are alcohol, ether, and hydrocarbon.

### (B) Mesoporous Film

The mesoporous film is a porous material film in which the diameter of pores formed by removing the template from the oxide mesostructured film is 2 to 50 nm and the wall portion contains an oxide. (The definition of the mesoporous definition is based on IUPAC (International Union of Pure and Applied Chemistry).) The wall portion surface may be modified as required. For example, in order to suppress adsorption of water, the surface may be modified with hydrophobic molecules.

### (3) Surfactant

Mentioned as an example of surfactant molecules are block copolymers containing a hydrophilic portion and a hydrophobic portion. As an example of the hydrophilic portion of the block copolymer, polyethylene glycol can be mentioned. As an example of the hydrophobic portion thereof, polypropylene glycol, polybutylene glycol, polystyrene, polybutadiene, and polymethyl methacrylate can be mentioned. As a specific example of the surfactant containing polyethylene glycol as the hydrophilic group, a block copolymer of polyethylene glycol, polypropylene glycol, and polyethylene glycol can be mentioned. A suitable surfactant is an amphiphilic substance.

In general, by the use of a large hydrophobic group and a large hydrophilic group, the pore diameter can be increased. In addition to the surfactant, additives for adjusting the structure period may be added. As the additives for adjusting the structure period, hydrophobic substances are mentioned. Mentioned as an example of the hydrophobic substances are alkanes and aromatic compounds not containing a hydrophilic group. As a specific example thereof, octane is mentioned.

### First Embodiment

### Method for Manufacturing an Orientated Oxide Mesostructured Film

One of methods for manufacturing the oxide mesostructured film according to this embodiment includes a process for performing a polycondensation reaction of an oxide precursor containing a silicon compound 1 represented by the following general formula (1) in the presence of a surfactant on a substrate having anisotropy in the orientation direction of molecules in the substrate plane to form an oxide mesostructured film having an oriented ordered structure in the film plane, in which the content of silicon (X′) of the silicon compound 1 to the number of atoms (Y′) of silicon or metallic elements among elements constituting the oxide precursor containing the silicon compound 1 is 0.1 or more and 0.5 or lower in terms of the atomic number ratio (X′/Y′).

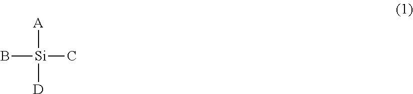

In the formula above, A represents an alkyl group having 8 or more carbon atoms. B, C, and D represent an alkoxy group, chlorine, bromine, or iodine. B, C, and D may be the same or may be different from each other.

The method for manufacturing the oriented oxide mesostructured film according to the embodiment of the invention is described while dividing the method into the following two processes:

(1) Process for preparing a substrate with anisotropic molecular orientation and (2) Process for giving an oxide precursor subjected to a polycondensation reaction in the presence of a surfactant to the substrate with anisotropic molecular orientation to form an oxide mesostructured film having an in-plane oriented ordered structure.

Each process is described in detail below.

(1) Process for Preparing a Substrate with Anisotropic Molecular Orientation

The use of a substrate in which the orientation of molecules present on the substrate surface (hereinafter referred to as a substrate with anisotropic molecular orientation) is anisotropic allows the formation of an oxide mesostructured film in which the orientation direction of structures is controlled in a given direction throughout in the substrate plane. Mentioned as the substrate with anisotropic molecular orientation are a substrate in which a material in which the orientation of molecules is anisotropic is formed on the surface of a general substrate and the like.

Although the quality of the materials of the general substrate is not particularly limited, one which is stable to a reaction solution is suitably used. As a specific example, glass, quartz, a semiconductor wafer (containing silicon), ceramics, resin (e.g., polyimide), metal, and the like are mentioned. A substrate to which a flexible film, such as plastic, is given and a substrate to which a transparent conductive film is given can also be used as required. The shape of the substrate can be selected without particular limitation. As an example, a plane and a curved surface are mentioned. When using a substrate, it is suitable to sufficiently clean the substrate to expose the clean surface. As an example of the cleaning method, organic solvent cleaning, water cleaning, acid treatment, and UV-ozone treatment are mentioned.

This process includes forming a material in which the in-plane orientation of molecules is anisotropic on the substrate surface. As a material in which the orientation of molecules is anisotropic, a polymer compound film and a Langmuir-Blodgett film (LB film) of a polymer compound which are subjected to rubbing treatment can be mentioned.

As these polymer compounds, one which has resistant to the formation process for the oxide mesostructured film and has molecular orientation anisotropy having orientation controlling force. As a specific example, polyimide is mentioned. As the polyimide, one containing two or more continuous methylene groups in repeated structural units is suitably used. As a technique for forming the polymer compound on a substrate, spin coating and the like are mentioned.

The rubbing treatment refers to treatment in which a polymer or the like on the substrate described above is rubbed in one direction with cloth or the like. Mentioned as an example of the rubbing treatment is treatment which is performed by disposing a rubbing cloth on a roller, bringing the roller which is made to rotate into contact with the substrate surface, and then moving a stage on which the substrate is fixed in one direction to the roller. As the rubbing cloth, one which is optimal to the polymer material to be used is selected and general one, such as nylon and cotton, can be used. The strength of the rubbing treatment is controlled based on parameters, such as the number of rotations of the roller, the distance between the substrate and the roller, the movement speed of the stage on which the substrate is fixed, and the like.

The LB film is a film obtained by transferring a monomolecular film developed on the water surface onto the substrate. This film can form a cumulative structure by repeating the film formation. The LB film according to a suitable embodiment of the invention contains a monomolecular cumulative film of a LB film derivative obtained by treating the LB film formed on the substrate by heat treatment or the like to change the chemical structure while maintaining the cumulative structure. Materials of the LB film are not particularly limited in the material quality insofar as the materials can achieve good orientation. As an example thereof, a polymer compound, such as polyimide, is mentioned.

For the film formation of the LB film, a general method is used. For example, the LB film is obtained by applying a surface pressure to a monomolecular layer developed on the water surface to thereby form monomolecular layers in a layer by layer manner on a substrate by dipping the substrate in and out of water. The shape and properties of the film are controlled by the surface pressure, the dipping speed when dipping the substrate in and out of water, the number of layers, and the like.

(2) Process for Giving an Oxide Precursor which is Subjected to a Polycondensation Reaction in the Presence of a Surfactant to a Substrate with Anisotropic Molecular Orientation to Form an Oxide Mesostructured Film Having an In-Plane Oriented Ordered Structure

In order to explain the contents of the process for the heading, the description is given while dividing the process into the following five processes.

### (2-1) Process for Preparing a Precursor Solution of an Oxide Mesostructure

### (2-2) Process for Giving a Precursor Solution of an Oxide Mesostructure to a Substrate

### (2-3) Process for Forming an Oxide Mesostructured Film Having an In-Plane Oriented Ordered Structure

### (2-4) Subsequent Processes and an Evaluation Method

### (2-1) Process for Preparing a Precursor Solution of an Oxide Mesostructure

Processes constituting this process are not particularly limited. For example, substances constituting a precursor solution are put in a solvent, and then stirred. These processes can be performed while controlling the atmosphere, the temperature, the humidity, the stirring intensity, and the like as required. Moreover, small processes, such as supersonic treatment and filtration, can be added as required.

The precursor solution of the oxide mesostructure contains an oxide precursor, a surfactant, a solvent, and water. With respect to the oxide precursor, one described in the section of the description of the term (1) Oxide can be used. With respect to the surfactant, one described in the section of the description of the term (3) Surfactant can be used.

For the solvent of the reaction solution, one capable of dissolving a precursor of an inorganic oxide and a surfactant is used. As an example thereof, an organic solvent and water are mentioned. As an example of the organic solvent, a polar solvent is mentioned. As a specific example thereof, alcohol and THF are mentioned. As an example of the alcohol, ethanol, propanol, methanol, and butanol are mentioned. A mixture of two or more kinds of solvents may be used.

To the reaction solution, substances other than the substances described above can be added as required. For example, a substance which has a function of a catalyst and adjusts the acidity and basicity of the reaction solution may be added. As an example of the substance for adjusting acidity and basicity, acids, such as hydrochloric acid, and bases, such as ammonium hydroxide, are mentioned. These substances are added in order to control the hydrolysis and the condensation reaction speed of a precursor substance in many cases.

A suitable manufacturing method of the invention includes performing a polycondensation reaction of the oxide precursor containing the silicon compound 1 represented by the following general formula (1) in the presence of a surfactant.

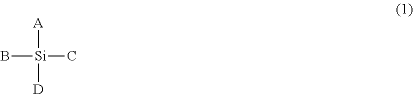

A represents an alkyl group having 8 or more carbon atoms. There is a feature in which the silicon compound 1 having an alkyl group having 8 or more carbon atoms is made to be coexistent. The silicon compound 1 is added into the precursor solution in this process.

The number of carbon atoms of the alkyl group of the silicon compound 1 is suitably 8 or more and 22 or lower. A reason why the number of carbon atoms is 8 or more resides in that a chain length equal to or loner than a given length is required in order to realize the interaction between alkyl groups, and when the chain length becomes equal to or longer than 8, sufficient interaction is obtained similarly as in a gold/alkanethiol system which is a typical self-organization film. On the other hand, although the upper limit of the number of carbon atoms of the alkyl group is 22 from the viewpoint of availability and dissolution in a solvent as an example, the number of carbon atoms may be 22 or more insofar as these points are satisfied. In order to obtain sufficient interaction, the alkyl chain is suitably a straight chain.

Functional groups represented by B, C, and D of the silicon compound 1 are selected from an alkoxy group, chlorine, bromine, or iodine. Mentioned as an example of the alkoxy group are an ethoxy group, a methoxy group, a propoxy group, and a butoxy group. B, C, and D may be the same or may be different from each other. A reason why the number of the alkyl chains directly bonded to one silicon atom of the silicon compound 1 is 1 resides in that, due to the fact that at least one alkyl chain is present, an aggregate is formed utilizing the interaction thereof to develop an orientation formation function as described later and that the number of the alkyl chains directly bonded to one silicon atom increases, the bond to be formed between the silicon atom and the oxide decreases, which makes it difficult to maintain the structure of the structure to be formed.

According to a suitable manufacturing method of the invention, the content of silicon (X′) of the silicon compound 1 to the number of atoms (Y′) of silicon or metallic elements among the elements constituting the oxide precursor containing the silicon compound 1 is 0.1 or more and 0.5 or lower in terms of the atomic number ratio (X′/Y′). It means that, for example, in the case where the oxides are silicon oxides, when the total number of silicon atoms which are contained in the oxide precursor substance given onto a substrate with anisotropic molecular orientation and finally form silicon bonded to oxygen is set to 1, silicon atoms of 0.1 or more and 0.5 or lower in terms of the atomic number ratio originate from the silicon compound 1. It means that, for example, in the case where the oxides are titanium oxides, when the sum of the total number of titanium atoms which are contained in the oxide precursor substance given onto a substrate with anisotropic molecular orientation and finally form titanium bonded to oxygen and the number of atoms of silicon of the silicon compound 1 contained in the precursor substance is set to 1, silicon atoms of 0.1 or more and 0.5 or lower in terms of the atomic number ratio originate from the silicon compound 1.

When the silicon compound 1 having an alkyl group in a mesostructure precursor is lower than 0.1 in terms of the atomic number ratio, the orientation of the oxide mesostructured film cannot be achieved. When it is higher than 0.5, it becomes difficult to maintain the in-plane ordered structure of the structures to be formed as a result of a reduction in the strength of the oxide network.

In the manufacturing method of the invention, a polycondensation reaction of an oxide precursor containing a silicon compound 2 represented by the following general formula (2) in addition to the silicon compound 1 may be performed in the presence of a surfactant.

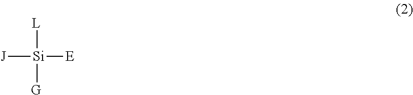

In the formula above, L represents a carbon atom to which a hydroxyl group is directly bonded. E, G, and J represent an alkoxy group, chlorine, bromine, or iodine. E, G, and J may be the same or may be different from each other.

The silicon compound 1 having an alkyl group functions as a part of the oxide precursor, forms an aggregate utilizing the interaction between alkyl groups, and develops an orientation formation function. By the introduction of the alkyl group into the oxide precursor, the precursor becomes hydrophobic as compared with one into which an alkyl group is not introduced. In the manufacturing method according to a suitable embodiment of the invention, the mesostructure is formed mainly due to the hydrophilic/hydrophobic contrast of a hydrophilic portion containing a complex of a hydrophilic domain of a surfactant and an oxide precursor and a hydrophobic portion containing a hydrophobic domain of a surfactant. Therefore, the introduction of the alkyl group into the precursor may somewhat suppress the formation ability of the mesostructure in some cases.

To solve the problem, the inventors have found that the structural regularity of the mesostructured film improves by introducing the silicon compound 2 in which a carbon atom, to which a hydrophilic hydroxyl group is directly bonded, is bonded to increase the hydrophilic/hydrophobic contrast.

The functional group represented by L of the silicon compound 2 is the carbon atom to which a hydroxyl group is directly bonded. When the hydroxyl group is directly bonded to silicon, the hydroxyl group (silanol group) is used for the condensation reaction to be lost. Therefore, the hydroxyl group does not greatly contribute to an increase of hydrophilicity. To that end, a carbon atom to which a hydroxyl group is directly bonded is suitably used for L. A functional group bonded to the carbon atom in addition to a hydroxyl group and silicon is not particularly limited. A hydroxyl group may be further bonded and oxygen may be bonded through the formation of a double bond. Moreover, one to which a hydrogen atom is bonded is most suitably used.

Functional groups represented by E, G, and J of the silicon compound 2 are selected from an alkoxy group, chlorine, bromine, or iodine similarly as in B, C, and D of the silicon compound 1.

With respect to a suitable content of the silicon compound 2, the content of silicon (Z′) of the silicon compound 2 to the number of atoms (Y′) of silicon or metallic elements among the elements constituting the oxide precursor containing the silicon compound 2 is 0.02 or more and 0.2 or lower in terms of the atomic number ratio (Z′/Y′). It means that, for example, in the case where the oxides are silicon oxides, when the total number of silicon atoms which are contained in the oxide precursor substance given onto a substrate with anisotropic molecular orientation and finally form silicon bonded to oxygen is set to 1, silicon atoms of 0.02 or more and 0.2 or lower in terms of the atomic number ratio originate from the silicon compound 2. It means that, for example, in the case where the oxides are titanium oxides, when the sum of the total number of titanium atoms which are contained in the oxide precursor substance given onto a substrate with anisotropic molecular orientation and finally form titanium bonded to oxygen and the number of atoms of silicon of the silicon compound 2 contained in the precursor substance is set to 1, silicon atoms of 0.02 or more and 0.2 or lower in terms of the atomic number ratio originate from the silicon compound 2.

When the silicon compound 2 in which carbon to which a hydroxyl group is bonded is directly bonded is lower than 0.02 in terms of the atomic number ratio in the mesostructure precursor, the hydrophilic/hydrophobic contrast cannot be effectively improved. When it is higher than 0.2, the oxide network strength becomes weak and the hydrophilic/hydrophobic contrast excessively improves, and therefore it becomes difficult to improve the in-plane ordered structure of a structure to be consequently formed.

### (2-2) Process for Giving the Precursor Solution of the Oxide Mesostructure to a Substrate

As a process for giving the precursor solution of the oxide mesostructure to a substrate, general coating method can be used. As an example thereof, a dip coating method, a casting method, a spin coating method, a spray coating method, an ink jet method, a pen lithography method, and the like are mentioned.

Among the above, the dip coating method and the spin coating method are effective as coating methods capable of simply forming a uniform film. The coating method by the dip coating method includes dipping a substrate in a reaction solution, and then pulling up the substrate to apply the solution onto the substrate. The application amount can be controlled based on the conditions of the coating and the production of the precursor solution. Mentioned as typical conditions are the composition of the solution and the substrate pulling-up speed. For example, the application amount (film thickness) generally decreases by increasing the proportion of the solvent in the reaction solution or by reducing the pulling-up speed.

This application is influenced by the surrounding environment. Therefore, the application can be carried out by controlling the atmosphere, the temperature, the solvent concentration in the atmosphere, and the like as required.

### (2-3) Process for Forming an Oxide Mesostructured Film Having an Oriented Ordered Structure

This process includes (2-3-1) the progress of a hydrolysis-polycondensation reaction of the oxide precursor and the silicon compound 1 in the precursor solution and (2-3-2) the self-assembling of the surfactant, the oxide precursor, and the silicon compound 1 on the substrate with anisotropic molecular orientation.

### (2-3-1) Progress of a Hydrolysis-Polycondensation Reaction of the Oxide Precursor and the Silicon Compound 1 in the Precursor Solution

An oxide precursor in a mesostructure precursor solution of oxide raw materials forms the framework of a mesostructure by the formation of oxides by a hydrolysis-polycondensation reaction. Although this reaction proceeds in a hydrophilic portion of the self-assembling structure of surfactant molecules on a substrate described later, the reaction can be already made to start also in a precursor solution prior to being given onto the substrate. The silicon compound 1 also participates in this hydrolysis-polycondensation, and forms an oxide-O—Si—R bond. Herein, R represents an alkyl group. The progress of this reaction can be controlled by the temperature, the solution composition, and the like.

(2-3-2) Self-Assembling of the Surfactant, the Oxide Precursor, and the Silicon Compound 1 on a Substrate with Anisotropic Molecular Orientation

When the mesostructure precursor solution is applied to a substrate with anisotropic molecular orientation by the process described in (2-2), a volatile solvent and the like are gradually lost from a liquid film on the substrate. In connection therewith, the concentrations of the surfactant, the oxide precursor which is at least partially hydrolyzed, and the silicon compound 1 which is at least partially hydrolyzed in the liquid film increase. When the surfactant concentration reaches the critical micellar concentration, surfactant molecules form micelles in such a manner that a hydrophobic group is directed to the inside and a hydrophilic group is directed to the outside to form a regular lyotropic liquid crystal layer. At this time, the hydrolyzed oxide precursor is accumulated in the hydrophilic portion of the lyotropic liquid crystal layer formed by the micelles. The hydrolyzed silicon compound 1 is taken in into the micelles of the lyotropic liquid crystal layer in such a manner that the Si—O portion is present in the hydrophilic portion and the alkyl chain is present in the hydrophobic portion. Furthermore, the polycondensation reaction proceeds between the hydrolyzed oxide precursors in the hydrophilic portion as the progress of the evaporation of the solvent, so that an oxide wall is formed around the hydrophobic portion of micelles. The silicon compound 1 also forms a bond of M-O—Si—R to be covalently bonded to the oxide. Herein, M is an element other than the oxygen constituting oxides. With such a mechanism, a mesostructure is formed on the substrate. With respect to the structure of the mesostructure to be formed, the final structure is almost determined depending on the oxide type at the end of the film formation process in some cases and the structure at the end of the film formation process greatly changes due to subsequent treatment and the like in some cases. Herein, the subsequent treatment refers to treatment of holding a formed film in water vapor, for example.

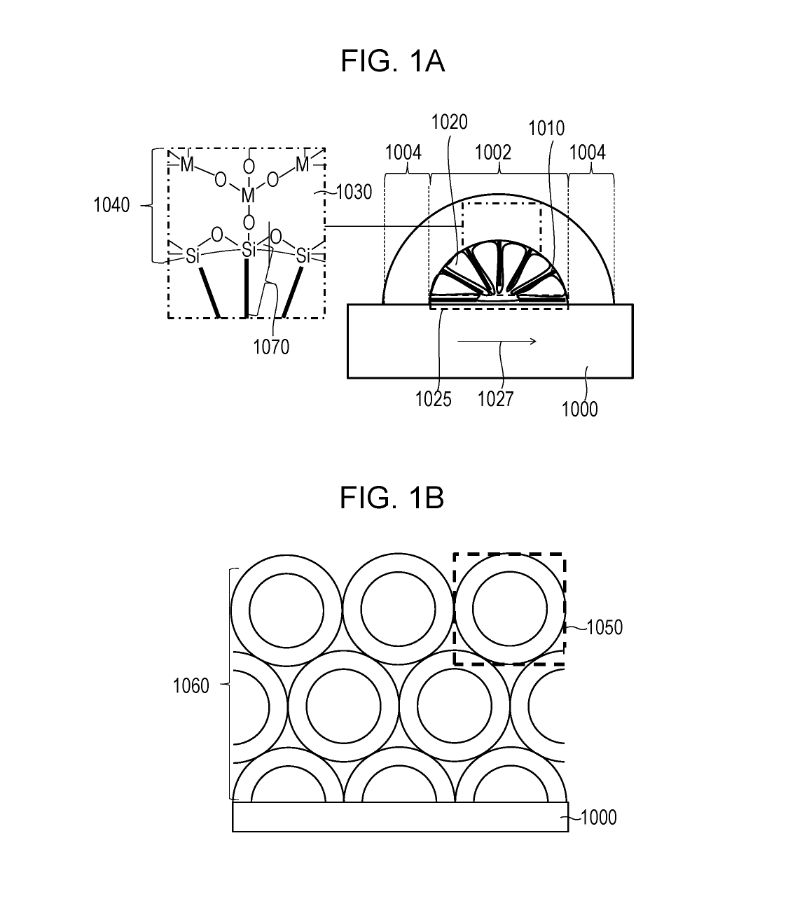

Herein, the interaction with the substrate with anisotropic molecular orientation is described. In the method for manufacturing the oxide mesostructure according to a suitable embodiment of the invention, it is considered in the formation of the mesostructure described above that alkyl groups of the silicon compound 1 are anisotropically disposed on the substrate with anisotropic molecular orientation, and thus has a function of forming an oriented oxide mesostructured film. This is described with reference to FIGS. 1A and 1B.

FIGS. 1A and 1B are views explaining the interaction between the oxide mesostructured film according to a suitable embodiment of the invention and the substrate with anisotropic molecular orientation.

### FIG. 1A

In FIG. 1A, a micelle containing a hydrophobic portion 1002 (inner side of a double circle in FIG. 1A) and a hydrophilic portion 1004 (a portion between the outer circle and the inner circle of the double circle in FIG. 1A) is formed on the surface of a substrate with anisotropic molecular orientation 1000 (in which the orientation direction of molecules is indicated by the arrow). The hydrophobic portion 1002 is constituted by alkyl chains 1010 (thick line in FIG. 1A) of the silicon compound 1 which is at least partially hydrolyzed and hydrophobic groups 1020 of the surfactant mainly present in the precursor solution of the mesostructure. Herein, the hydrophobic groups of the surfactant are not clearly illustrated for clarification of the drawings. It is considered that the hydrophobic groups mainly form the hydrophobic portion and are in a situation where the alkyl chains of the silicon compound 1 are embedded therein. The hydrophobic portion is bonded to the hydrophilic portion of the surfactant. The alkyl chains 1010 of the silicon compound 1 are disposed in such a manner as to be oriented in parallel to the orientation direction of the molecules on the substrate on the entire substrate due to anisotropic interaction with the substrate. The reference numeral 1027 denotes the orientation direction of the molecules in the substrate plane.

Based on the mechanism described above, a mesostructure having a structure in which the hydrophobic groups 1020 of the surfactant and the alkyl chain micelle of the silicon compound 1 are surrounded with an oxide wall 1040 in which hydrophilic groups (present in a portion 1030) of the surfactant and the silicon compound 1 (1070) are bonded is formed on the substrate with the volatilization of the solvent in the solution. At this time, the silicon compound 1 which is anisotropically disposed on the surface and is at least partially hydrolyzed serves as the starting point on the substrate of the micelle structure formation of the mesostructure.

### FIG. 1B

In FIG. 1B, when the solution composition is appropriate, an oxide mesostructure 1060 in which the orientation of cylinders 1050 having orientation properties constituted by the above-described micelles is controlled is formed from the starting point in connection with the solvent evaporation. Depending on the oxide type, the mesostructure changes to the cylindrical structure in the treatment process after the film formation described above. At that time, the silicon compound 1 is similarly anisotropically disposed on the surface, and subsequently the oriented mesostructure is formed.

### (2-4) Subsequent Process and Evaluation

### (2-4-1) Process for Removing the Surfactant

The method for manufacturing the oxide mesostructured film of the invention may also include a process for removing the surfactant as required. The method is not particularly limited, and methods, such as decomposition removal and extraction, can be used. As an example of the former method, methods by means of calcination, UV irradiation, and O₃ are mentioned. As an example of the latter method, methods by means of a solvent or a supercritical fluid are mentioned.

In the removal of the amphiphilic substance by calcination, the amphiphilic substance can be almost completely removed from the porous film. The calcination temperature and time change depending on the type of the amphiphilic substance held therein. As a specific example, the temperature in the range of 300 to 600° C. and the time in the range of 15 minutes to 24 hours are mentioned, for example. When a solvent extraction method is used, a complete (100%) removal of the amphiphilic substance is difficult but the method is advantageous in holding the structure when removing the template.

The calcination process has the above-described merits. On the other hand, there is a possibility that the structural regularity of the oxide mesostructured film is disturbed to collapse the structure. This is considered to be because the structure of the oxide changes due to a high temperature environment during calcination. In order to prevent the problem, it is considered to be effective to strengthen the pore wall of the oxide mesostructured film and to suppress the growth of crystals of the oxides. As an example of specific methods thereof, a method is mentioned which includes allowing a precursor of on oxide, such as silicon oxide, to react after the formation of an oxide mesostructured film of oxides to at least partially form oxides, such as silicon oxide. By the use of this method, disturbing the structural regularity of the oxide mesostructured film can be suppressed even while removing the surfactant by calcination. When preparing the mesoporous film, this technique can be applied as required.

### (2-4-2) Evaluation

The oxide mesostructured film according to a suitable embodiment of the invention is an oxide mesostructured film in which the orientation direction of the structures in the substrate plane is controlled in one direction over the entire substrate. Mentioned as an example of the mesostructure of the film are a cylindrical structure in which structures are disposed in the shape of a honeycomb which is generally referred to as a two-dimensional hexagonal structure and one in which spherical structures are hexagonally packed or face-centered packed. Among the above, the two-dimensional hexagonal structure is the most suitable (hereinafter, the state where the orientation direction of structures is controlled in a given direction throughout in the substrate plane is sometimes referred to as “uniaxial orientation”).

The oxide mesostructured film of the invention can be evaluated by performing transmission electron microscope (TEM) observation, scanning electron microscope (SEM) observation, atomic force microscope observation, X-ray diffraction (XRD) analysis, infrared spectrum (IR) measurement, ultraviolet and visible light absorption spectrum measurement, fluorescence spectrum measurement, X-ray photoelectron spectroscopy (XPS), and the like.

It can be investigated whether or not the film prepared using the manufacturing method of the invention is an oxide mesostructured film by the microscope observation or the XRD analysis described above.

The structural regularity of the oxide mesostructured film prepared using the manufacturing method of the invention can be investigated by performing the microscope observation or the XRD analysis. For example, the structure period of the oxide mesostructured film can be confirmed by performing XRD analysis (X-ray diffraction measurement generally referred to as θ/2θ scan) in the Bragg-Brentano geometry, and then calculating the plane spacing corresponding to the angle which gives a diffraction peak.

The relationship of the angle, the plane spacing, and the wavelength of X-rays to be used is simply represented by the Bragg equation:

nλ=2d sin θ (1).

For example, when a diffraction peak which gives θ=1° appears in the measurement using Cu-Kα rays with a wavelength of 0.1542 nm, the plane spacing is 4.42 nm. When a diffraction peak which gives θ=2° appears, the plane spacing is 2.21 nm.

It can be investigated by performing XRD analysis whether or not the structure of the oxide mesostructured film having a structural regularity obtained using the manufacturing method of the invention is a cylindrical structure in which structures are disposed in the shape of a honeycomb. For example, it can be confirmed by obtaining a two-dimensional X-ray diffraction pattern of the oxide mesostructured film, and then observing the appearance of the (10) (−11) spot, which is characteristic in the cylindrical structure in which structures are disposed in the shape of a honeycomb, in addition to the (01) spot in the pattern. It can also be confirmed by performing microscope observation of the cross section of the film as required.

As a method for quantitatively evaluating that the orientation direction of the structures in the oxide mesostructured film obtained using the manufacturing method of the invention is a given direction throughout in the substrate plane, an evaluation method by means of in-plane XRD analysis is mentioned. The method measures the in-plane rotation dependence of the XRD intensity originating from a plane which is not parallel to the film plane, and can investigate the orientation direction and distribution of the cylindrical structures.

Specifically, the orientation distribution in the same plane can be investigated by measuring the plane spacing by radial scan of the XRD analysis, confirming the periodic structure in the plane, and then performing rocking curve measurement for the diffraction peak thereof. In the in-plane X-ray diffraction analysis, the incident angle of X-rays is very small (about 0.2°, as an example), and therefore a wide range of the film (cm order, as an example) is an analysis target. Thus, the structure information obtained by the in-plane XRD analysis can be treated as structure information in a wide range in the film. In this analysis, when the orientation direction of the cylindrical structures is a given direction throughout in the substrate plane, two diffraction peaks which are 180° apart are observed in the rocking curve in the same plane when evaluating by the in-plane X-ray diffraction. Herein, the description of “180° apart” means that the interval of the two peaks is in the range of 180±1°. In the oxide mesostructured film according to a suitable embodiment of the invention, the X-ray diffraction peak in the same plane observed as two peaks shows the substantially same diffraction intensity. Herein, the description that the X-ray diffraction peak in the same plane observed as two peaks shows the substantially same diffraction intensity means that a value obtained by dividing a value of the peak intensity of the peak exhibiting high intensity by a value of the peak intensity of the peak exhibiting low intensity is 1 or more and lower than 1.5.

When the half width value of the peaks observed by the rocking curve measurement in the same plane is within 80°, suitably within 40°, and more suitably within 20°, the orientation direction of the structures is in one direction throughout in the film plane.

### Second Embodiment

### Oxide Mesostructured Film

An oxide mesostructured film according to this embodiment contains oxides which are formed by performing a polycondensation reaction of an oxide precursor containing the silicon compound 1 represented by general formula (1) above in the presence of a surfactant and is an oxide mesostructured film having a structure in which the cylindrical structures are packed in the shape of a honeycomb, in which the orientation direction of the cylindrical structures is a given direction throughout in the film plane, at least one peak appears in an angle region corresponding to the plane spacing of 8 nm or more in the X-ray diffraction measurement in the Bragg-Brentano geometry, and the number of atoms (X) of silicon to which an alkyl group having 8 or more carbon atoms is bonded to the number of atoms (Y) of silicon or metallic elements among elements constituting the oxides of the oxide mesostructured film described above is 0.1 or more and 0.5 or lower in terms of the atomic number ratio (X/Y).

The oxide mesostructured film according to an embodiment of the invention is described.

Recently, a study on increasing the structure period of the oxide mesostructure has been vigorously performed. As a method for increasing the structure period, a method for increasing the molecular amount (particularly the molecular amount of a hydrophobic group) of template molecules is mentioned. When the method is applied to the preparation of a uniaxially oriented oxide mesostructured film utilizing the molecular orientation anisotropy of the substrate, the following problem arises. Since an alkyl group which is a hydrophobic group of a surfactant having a strong interaction with the substrate with anisotropic molecular orientation has low solubility in a solvent having compatibility with water required for the formation of micelles when the chain length is equal to or longer than a given length, an oxide mesostructured film cannot be prepared in some cases.

The present inventors have achieved an object of realizing an oxide mesostructured film having the large structure period by giving, to an alkylsilicon compound which can be bonded to an oxide, an orientation formation function which has been performed by a surfactant containing an alkyl group heretofore.

The oxide mesostructured film of the invention is suitably provided on a substrate having anisotropy in the orientation direction of the molecules in the substrate plane. The orientation direction of the cylindrical structures of the oxide mesostructured film of the invention is suitably a perpendicular or almost perpendicular direction to the orientation direction of the molecules in the substrate described above. The almost perpendicular direction represents an angle of ±30° and suitably ±10° or lower based on the perpendicular direction.

The oxide mesostructured film of a suitable embodiment of the invention has a structure in which the cylindrical structures are packed in the shape of a honeycomb and the orientation direction of the cylindrical structures is a given direction throughout in the substrate plane. This structure can be confirmed by the method described in the section (2-4-2) of the first embodiment.

The oxide mesostructured film according to a suitable embodiment of the invention shows at least one peak in an angle region (angle region corresponding to the lattice plane spacing d≧8 nm) corresponding to the plane spacing of 8 nm or more in the X-ray diffraction measurement in the Bragg-Brentano geometry. This value has not been able to achieve by an alkyl surfactant capable of relatively easily forming the uniaxially oriented structure which has been used heretofore. On the other hand, the oxide mesostructured film which is formed with a surfactant capable of giving this value as a template has not been able to control the orientation in the film plane using the chemical interaction of a substrate with anisotropic molecular orientation and substances constituting the oxide mesostructured film. The maximum value of the lattice plane spacing is 50 nm from the definition of mesoporous.

The present inventors have found that the formation of the oxide mesostructured film having a large structure period can be achieved by giving, to an alkylsilicon compound which can be bonded to an oxide, an orientation formation function which has been performed by a surfactant containing an alkyl group, and thus has accomplished the invention. One aspect of the invention has a feature in that the number of atoms (X) of silicon to which an alkyl group having 8 or more carbon atoms is bonded to the number of atoms (Y) of silicon or metallic elements among elements constituting the oxide mesostructured film is 0.1 or more and 0.5 or lower in terms of the atomic number ratio (X/Y). The atomic number ratio means that, for example, when the oxides are silicon oxides, silicon atoms of 0.1 or more and 0.5 or lower in terms of the number of atoms are alkyl silicon compounds when the total number of silicon atoms of the silicon oxides contained in the mesostructure is set to 1. More specifically, the number of atoms (X″) of silicon to which an alkyl group having 8 or more carbon atoms is bonded to the number of atoms (Y″) of silicon of silica constituting the mesostructured film is 0.1 or more and 0.5 or lower in terms of the atomic number ratio (X″/Y″).

The atomic number ratio means that when the oxides are titanium oxides, the proportion of the alkylsilicon compounds is 0.1 or more and 0.5 or lower in terms of the number of atoms when the sum of the total number of titanium atoms contained in the titanium oxides contained in the mesostructured film and the total number of silicon atoms contained in the silicon oxide equivalent to the alkylsilicon compound is set to 1. When the proportion of the silicon compound 1 having an alkyl group is lower than 0.1 in terms of the atomic number ratio in the mesostructure precursor, the orientation of the oxide mesostructured film cannot be achieved. When the proportion thereof is higher than 0.5, it becomes difficult to hold the in-plane ordered structure of structures formed as a result of a reduction in the oxide network strength. This ratio can be controlled by changing the charging ratio of the oxide precursor serving as the raw material. This value can also be quantified by X-ray photoelectron spectroscopy or the like.

As described in (2-1) of the first embodiment, it is suitable in the alkylsilicon compound that a linear alkyl group having 8 or more carbon atoms is bonded to one silicon atom.

In the oxide mesostructured film according to a suitable embodiment of the invention, the orientation direction of the alkyl chains on the substrate surface is determined by the intermolecular interaction of the alkyl chains of the alkylsilicon compound and the substrate with anisotropic molecular orientation. As illustrated in FIGS. 1A and 1B, the alkyl chains are disposed substantially in parallel to the molecular orientation of the substrate. Surfactants are self-assembled in such a manner that the alkyl group is disposed in the hydrophobic site of micelles and oxides are formed in the hydrophilic portion, so that a mesostructure is formed. The oxide is bonded to the alkylsilicon compound at the interface through the formation of a Si—O—M bond. Due to such a formation mechanism, the orientation of the alkyl chains of the alkylsilicon compound at the interface gives orientation to the entire structure on the substrate with anisotropic molecular orientation. As a result, the orientation direction of the cylinders to be formed is a direction substantially perpendicular (perpendicular to the paper in FIGS. 1A and 1B) to the orientation direction of the molecules of the substrate.

The oxide mesostructured film according to a suitable embodiment of the invention has features in that the oxide mesostructured film is an oxide mesostructured film having a structure in which the cylindrical structures are packed in the shape of a honeycomb, the orientation direction of the cylindrical structures is a given direction throughout in the film plane, the number of atoms (X) of silicon to which an alkyl group having 8 or more carbon atoms is bonded to the number of atoms (Y) of silicon or metallic elements among elements constituting the oxides of the oxide mesostructured film is 0.1 or more and 0.5 or lower in terms of the atomic number ratio (X/Y), and the number of atoms (Z) of silicon to which carbon, to which a hydroxyl group is bonded, is bonded is 0.02 or more and 0.2 or lower in terms of the atomic number ratio (Z/Y).

The present inventor have found that an improvement of the structural regularity of the oriented oxide mesostructured film using the alkylsilicon compound can be achieved by the introduction of the silicon compound 2 in which a carbon atom, to which a hydrophilic hydroxyl group is directly bonded, is bonded as described above, and thus have accomplished the invention. The invention has features in that the number of atoms (X) of silicon to which an alkyl group having 8 or more carbon atoms is bonded to the number of atoms (Y) of silicon or metallic elements among elements constituting the oxides of the oxide mesostructured film is 0.1 or more and 0.5 or lower in terms of the atomic number ratio (X/Y) and the number of atoms (Z) of silicon to which carbon, to which a hydroxyl group is directly bonded, is bonded to the number of atoms (Y) is 0.02 or more and 0.2 or lower in terms of the atomic number ratio (Z/Y). This atomic number ratio means that, for example, when the oxides are silicon oxides, carbon, to which a hydroxyl group is directly bonded, is bonded to silicon atoms having a proportion of 0.02 or more and 0.2 or lower in terms of the number of atoms when the total number of silicon atoms of the silicon oxides contained in the mesostructure is set to 1. More specifically, the number of atoms (X″) of silicon to which an alkyl group having 8 or more carbon atoms is bonded to the number of atoms (Y″) of silicon of silica constituting the mesostructured film is 0.1 or more or 0.5 or lower in terms of the atomic number ratio (X″/Y″). The number of atoms (Z″) of silicon to which carbon, to which a hydroxyl group is directly bonded, is bonded to the number of atoms (Y″) is 0.02 or more and 0.2 or lower in terms of the atomic number ratio (Z″/Y″).

The atomic number ratio means that, in the case where the oxides are titanium oxides, when the sum of the total number of titanium atoms contained in the titanium oxides contained in the mesostructured film and the total number of silicon atoms contained in the silicon oxides equivalent to the alkylsilicon compounds is set to 1, the proportion of the alkylsilicon compounds is 0.1 or more and 0.5 or lower in terms of the number of atoms and the number of atoms of silicon to which carbon, to which a hydroxyl group is directly bonded, is bonded is 0.02 or more and 0.2 or lower in terms of the atomic number ratio.

When the proportion of silicon atoms to which carbon, to which a hydroxyl group is directly bonded, is bonded is lower than 0.02 in terms of the atomic number ratio in the mesostructure precursor, the hydrophilic/hydrophobic contrast cannot be effectively improved. When the proportion thereof is higher than 0.2, the oxide network strength becomes weak and the hydrophilic/hydrophobic contrast excessively improves, and, as a result, it becomes difficult to hold the in-plane ordered structure of the structure. This value can be quantified by X-ray photoelectron spectroscopy or the like.

It is considered that the orientation direction of the oxide mesostructured film according to the invention originates from the interaction of molecules of an oxide precursor constituting a micelle containing a surfactant/an oxide precursor complex and the substrate with anisotropic molecular orientation. More specifically, the interaction between very fine substances of a molecular level serves as the driving force of the orientation formation. As a result, as compared with the orientation formed by a physical relationship of a reported aggregate and the shape anisotropy of a substrate larger than the aggregate, more precise orientation control can be achieved, and an orientation with a narrow distribution can be formed. Moreover, the oxide mesostructured film according to a suitable embodiment of the invention is advantageous also in that since a substrate having an anisotropic shape with irregularities is not required to use for the preparation thereof as a substrate for preparing the same, surface roughness resulting from the irregularities can be avoided. The avoidance of the surface roughness is very important for optical application which is potential as an application of the structure film.

### EXAMPLES

The invention is described in more detail below with reference to Examples, but the invention is not limited only to the Examples.

### Example 1

This example describes a method for manufacturing a uniaxially oriented silicon oxide mesostructured film using a block copolymer (ethylene oxide (20) propylene oxide (70) ethylene oxide (20): (hereinafter referred to as EO(20) PO(70) EO(20)) as a surfactant and tetraethoxysilane and alkyltriethoxysilane as an oxide precursor.

### (1-1) Experiment

(1-1-1) Process for Preparing Substrate with Anisotropic Molecular Orientation

A silicon wafer (100) was subjected to UV-ozone cleaning, and then an N-methylpyrrolidone solution of polyamic acid which is a precursor of polyimide represented by the following structural formula was applied thereto by spin coating, followed by calcination at 200° C. for 1 hour, thereby obtaining a polyimide thin film having the following structure.

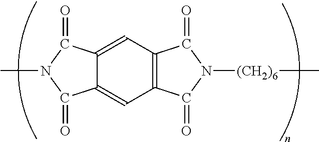

The substrate was entirely subjected to rubbing treatment in one direction, thereby preparing a substrate with anisotropic molecular orientation.

(1-1-2) Process for Forming an Oxide Mesostructured Film Having an Oriented Ordered Structure in the Film Plane by Performing a Polycondensation Reaction of an Oxide Precursor in the Presence of a Surfactant, and then Giving the Same Onto the Substrate

This process is described while dividing the same into the following two processes.

### (1-1-2-1) Process for Preparing a Precursor Solution of an Oxide Mesostructure

As alkyltriethoxysilane corresponding to a silicon compound 1 among oxide precursors, n-octyl triethoxysilane (Number of carbon atoms of 8), n-dodecyl triethoxysilane (Number of carbon atoms of 12), and n-octadecyl triethoxysilane (Number of carbon atoms of 18) are used. As a comparison target, an oxide mesostructured film using n-hexyl triethoxysilane (Number of carbon atoms of 6) is prepared.

A precursor solution of the oxide mesostructured film is prepared by adding an ethanol (THF for octadecyl triethoxysilane) solution of the block copolymer EO(20) PO(70) EO(20) to a solution obtained by mixing ethanol (THF for octadecyl triethoxysilane), 0.01 M hydrochloric acid, tetraethoxysilane, and alkyltriethoxysilane for 15 minutes, and then stirring the mixture for 1.5 hours. The mixing ratio (molar ratio) is as follows: tetraethoxysilane: 0.5, alkyltriethoxysilane: 0.5, hydrochloric acid: 0.0011, (water (contained in hydrochloric acid): 6) ethanol: 5.2 (3.7 in the case of THF), block copolymer: 0.0096, and ethanol (for dissolution of block copolymer): 3.5 (2.5 in the case of THF). The solution is diluted as appropriate for use for the purpose of film thickness adjustment.

The content (Atomic number ratio: (X′/Y′)) of silicon of the alkyltriethoxysilane corresponding to the silicon compound 1 of the oxide precursor is 0.5.

### (1-1-2-2) Process for Forming an Oxide Mesostructured Film Having an Ordered Structure by the Application to the Substrate

Film formation is performed on the silicon substrate prepared in the process (1-1-1) using a spin coating device. The rotation speed is 3000 or 5000 rpm. Thereafter, the substrate is allowed to stand for 24 hours or longer, and then evaluation is performed.

### (1-1-3) Evaluation Process

The XRD pattern is recorded using CuKα rays with an X-ray diffraction device (Rigaku ATX-G). In the measurement of the out-of-plane XRD, XRD (X-ray diffraction measurement generally referred to as θ/2θ scan) in the Bragg-Brentano geometry is performed, and then the plane spacing corresponding to the angle which gives a diffraction peak is calculated. In the in-plane XRD measurement, the incident angle to the substrate plane is set to 0.2°, the plane spacing is measured by radial scan (2θχ/φ scan) to confirm the periodic structure in the plane, and then the orientation distribution in the same plane is investigated by performing rocking curve measurement (φ scan) for the diffraction peak. A cross-sectional SEM image is obtained using a scanning electron microscope (HITACHI S-5500).

### (1-2) Results

Table 1 shows the list of the profiles of the oxide mesostructured films prepared in this example.

TABLE 1

| | | Lattice plane |
|---|---|---|
| Number of carbon | Half width value of | measured by out- |
| atoms of silicon | rocking curve of | of-plane XRD |
| compound 1 | in-plane XRD (/°) | (spacing/nm) |
| 8 | 50 | 9.4 |
| 12 | 32 | 9.4 |
| 18 | 46 | 9.4 |
| 6 (Comparison | Anisotropy of in- | 9.4 |
| target) | plane periodic | |
| | structure cannot be | |
| | confirmed. | |

It is confirmed from Table 1 that the oxide mesostructured films prepared using alkyltriethoxysilanes having carbon atoms of 8, 12, and 18 have an in-plane oriented ordered structure. Furthermore, it is confirmed from the two-dimensional XRD pattern and the cross-sectional SEM image that all of the oxide mesostructured films have a two-dimensional hexagonal structure. Moreover, it is confirmed that the rocking curve profile of the in-plane XRD of the oxide mesostructured films shows the peak in a direction of ±90° to the rubbing direction and the orientation direction of cylindrical structures is a direction perpendicular to the rubbing direction of the substrate.

The following items are confirmed from this example based on the results above.

A. In the manufacturing method according to the invention, the use of the silicon compound containing an alkyl chain having 8 or more carbon atoms as the silicon compound 1 allows the formation of the oxide mesostructured films having an in-plane oriented ordered structure.
B. The oxide mesostructured films prepared using the silicon compound containing an alkyl chain having 8 or more carbon atoms as the silicon compound 1 are oxide mesostructured films having a structure in which cylindrical structures are packed in the shape of a honeycomb. The orientation direction of the cylindrical structures is a given direction throughout in the film plane.
C. When CuKα rays are used as incident X-rays in the X-ray diffraction measurement in the Bragg-Brentano geometry, the prepared oxide mesostructured films show the peak of Bragg reflection in the angle region equivalent to the lattice plane spacing d=9.4.
D. In the prepared oxide mesostructured films, the atomic number ratio (X/Y) of the alkylsilicon compounds to all the oxides constituting the oxide mesostructured film is 0.5.
E. The oxide mesostructured films having the in-plane ordered structure are prepared on the substrate with anisotropic molecular orientation in such a manner as to contact the substrate.
F. The orientation direction of the cylindrical structures of the oxide mesostructured films prepared using the silicon compound containing an alkyl chain having 8 or more carbon atoms as the silicon compound 1 is perpendicular to the direction showing the anisotropy of the substrate with anisotropic molecular orientation.

### Example 2

This example describes a method for manufacturing a uniaxially oriented silicon oxide mesostructured film using the block copolymer EO(20) PO(70) EO(20) for a surfactant and using tetraethoxysilane and dodecyltriethoxysilane as an oxide precursor.

### (2-1) Experiment

(2-1-1) Process for Preparing a Substrate with Anisotropic Molecular Orientation

A substrate with anisotropic molecular orientation was prepared using the same technique as in (1-1-1).

(2-1-2) Process for Forming an Oxide Mesostructured Film Having an Oriented Ordered Structure in the Film Plane by Performing a Polycondensation Reaction of an Oxide Precursor in the Presence of a Surfactant, and then Giving the Same Onto the Substrate

This process is described while dividing the same into the following two processes.

### (2-1-2-1) Process for Preparing a Precursor Solution of an Oxide Mesostructure

As a compound corresponding to the silicon compound 1, n-dodecyltriethoxysilane was used. A precursor solution of an oxide mesostructured film was prepared by adding an ethanol solution of a block copolymer EO(20) PO(70) EO(20) to a solution obtained by mixing ethanol, 0.01 M hydrochloric acid, tetraethoxysilane, and n-dodecyltriethoxysilane for 15 minutes, and then stirring the mixture for 1.5 hours. The mixing ratio (molar ratio) is as follows: tetraethoxysilane: (1-x), n-dodecyltriethoxysilane: x, hydrochloric acid: 0.0011, (water (contained in hydrochloric acid): 6) ethanol: 5.2, and block copolymer: 0.0048-0.0192:ethanol (for dissolution of the block copolymer) 3.5. X represents the atomic number ratio of silicon contained in the oxide precursor derived from the silicon compound 1 when the number of atoms of silicon or metallic elements among the elements constituting the oxide precursor is set to 1 or the atomic number ratio of silicon contained in the alkylsilicon compound when the number of atoms of silicon or metallic elements constituting the oxide mesostructured film is set to 1.

As Example, solutions in which the atomic number ratio x of the silicon compound 1 was set to 0.1, 0.3, and 0.5 were prepared. Separately, solutions in which the atomic number ratio x of the silicon compound 1 is set to 0.01 and 0.7 were prepared as a comparison target.

The solution was diluted as appropriate for use for the purpose of film thickness adjustment.

### (2-1-2-2) Process for Application to the Substrate and Process for Forming an Oxide Mesostructured Film Having an Ordered Structure

Film formation is performed on the silicon substrate prepared in the process (2-1-1) using a spin coating device (Rotation speed of 3000 or 5000 rpm). Thereafter, the substrate was allowed to stand for 24 hours or longer, and then evaluation was performed.

### (2-1-2-3) Process for Removing a Template

The prepared oxide mesostructured films are immersed in ethanol, and then held at 80° C. for 8 hours to thereby remove the template.

### (2-1-3) Evaluation Process

The XRD pattern is recorded using CuKα rays with an X-ray diffraction device (Rigaku ATX-G). The removal of the template is confirmed by the IR spectrum based on a reduction in the peak at 830 to 880 cm⁻¹ derived from C—CH₃ in the template molecules.

### (2-2) Results

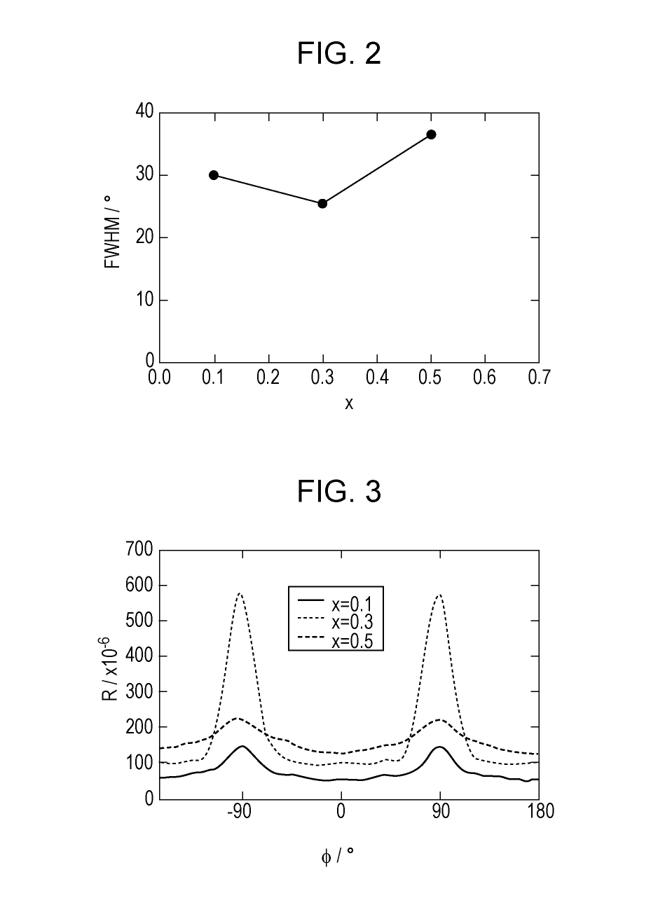

FIG. 2 illustrates the half width value of the rocking curve of the in-plane XRD to the value of the atomic number ratio x of the silicon compound 1 of the oxide mesostructured films prepared in Example 2. In FIG. 2, the horizontal axis represents the atomic number ratio x of the silicon compound 1 and the vertical axis represents the half width value of the rocking curve of the in-plane XRD. It was confirmed from FIG. 2 that when X is 0.1 or more and 0.5 or lower, the oxide mesostructured films have an in-plane oriented ordered structure.

On the other hand, the samples in which x was set to 0.01 and 0.7 prepared as a comparison target did not show a diffraction pattern showing the in-plane ordered structure.

FIG. 3 illustrates the in-plane rocking curve profile of the oxide mesostructured films prepared in Example 2. In FIG. 3, the horizontal axis represents the angle φ of the incident X-rays to the rubbing direction and the vertical axis represents the reflectance R of the X-rays. These profiles showed the peak in a direction of ±90° to the rubbing direction.

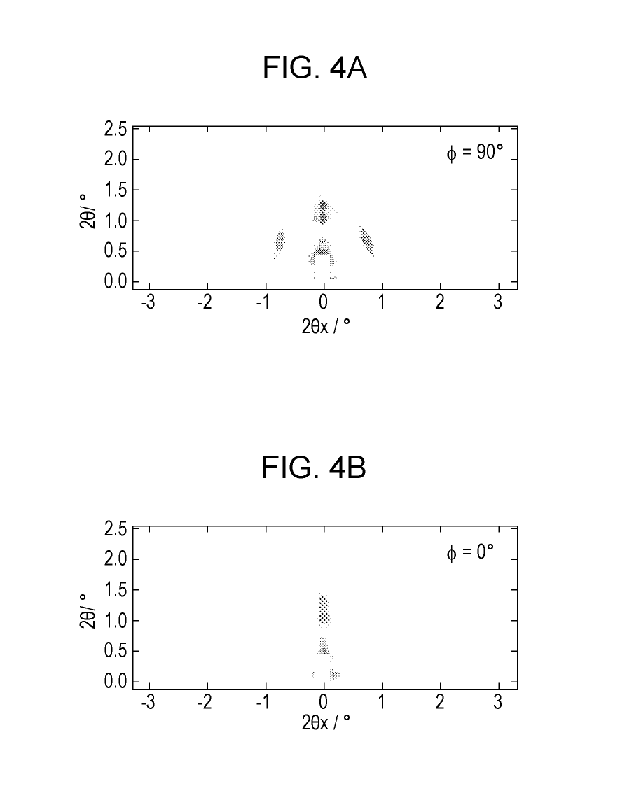

FIGS. 4A and 4B illustrate two-dimensional XRD patterns when the atomic number ratio x of the silicon compound 1 of the oxide mesostructured films prepared in Example 2 is 0.3. In FIGS. 4A and 4B, the vertical axis represents the angle of a direction perpendicular to the substrate plane and the horizontal axis represents the angle of the substrate in-plane direction. FIG. 4A illustrates a pattern when the incident direction of X-rays is 90° to the rubbing direction. FIG. 4B illustrates a pattern when the incident direction of X-rays is 0° to the rubbing direction. It was confirmed from FIGS. 4A and 4B that the oxide mesostructured films have a two-dimensional hexagonal structure with orientation anisotropy.

In the samples of this example and the samples as a comparison target, the plane spacing determined from the 2θ peak angle of the out-of-plane XRD was 8 nm or more and 11 nm or lower. Even after the removal of the template, the oxide mesostructured film holds the mesostructure, and the removal of the template is confirmed by the IR spectrum.

The following items are confirmed from this example based on the results above.

A. In the manufacturing method according to the invention, due to the fact that the atomic number ratio of the oxide precursors derived from the silicon compound 1 to the silicon or metal atoms contained in all the oxide precursors constituting the oxide precursors is 0.1 or more and 0.5 or lower, the oxide mesostructured films having an in-plane oriented ordered structure can be formed.
B. The oxide mesostructured films prepared under the conditions where the atomic number ratio of silicon contained in the oxide precursor derived from the silicon compound 1 is 0.1 or more and 0.5 or lower are oxide mesostructured films having a structure in which cylindrical structures are packed in the shape of a honeycomb. The orientation direction of the cylindrical structures is a given direction throughout in the film plane.
C. When CuKα rays are used as incident X-rays in the X-ray diffraction measurement in the Bragg-Brentano geometry, the prepared oxide mesostructured films show the peak of Bragg reflection in the angle region corresponding to d≧8 nm.
D. In the prepared oxide mesostructured films having an in-plane oriented ordered structure, when the number of atoms of silicon or metallic elements among the elements constituting oxides of the oxide mesostructured films is set to 1, the atomic number ratio of silicon of the alkylsilicon compound is 0.1 or more and 0.5 or lower.
E. The oxide mesostructured films having the in-plane ordered structure are prepared on the substrate with anisotropic molecular orientation in such a manner as to contact the substrate.
F. The orientation direction of the cylindrical structures of the prepared oxide mesostructured films having the in-plane oriented ordered structure is perpendicular to the direction showing the anisotropy of the substrate with anisotropic molecular orientation.
G. The oxide mesostructured films having the in-plane oriented ordered structure can be formed into mesoporous films.

### Example 3

This example describes a method for manufacturing a uniaxially oriented titanium oxide-silicon oxide complex oxide mesostructured film using a block copolymer EO(20) PO(70) EO(20) for a surfactant and titanium tetraisopropoxide and dodecyltrichlorosilane as an oxide precursor.

### (3-1) Experiment

(3-1-1) Process for Preparing a Substrate with Anisotropic Molecular Orientation

A substrate with anisotropic molecular orientation was prepared using the same technique as in (1-1-1).

(3-1-2) Process for Forming an Oxide Mesostructured Film Having an Oriented Ordered Structure in the Film Plane by Performing a Polycondensation Reaction of an Oxide Precursor in the Presence of a Surfactant, and then Giving the Same Onto the Substrate

This process is described while dividing the same into the following two processes.

### (3-1-2-1) Process for Preparing a Precursor Solution of an Oxide

As a compound corresponding to the silicon compound 1, n-dodecyltrichlorosilane was used. A precursor solution of an oxide mesostructured film is prepared by adding an ethanol solution of the block copolymer EO(20) PO(70) EO(20) to a solution obtained by mixing concentrated hydrochloric acid, titanium tetraisopropoxide, and n-dodecyltrichlorosilane for 5 minutes, and then stirring the mixture for 1.5 hours. The mixing ratio (molar ratio) is as follows: titanium tetraisopropoxide: 0.7, n-dodecyltrichlorosilane: 0.3, hydrochloric acid: 1.764, (water (contained in hydrochloric acid): 6), block copolymer: 0.0021, and ethanol: 14. The solution is diluted as appropriate for use for the purpose of film thickness adjustment. The content (Atomic number ratio) x of silicon of the n-dodecyltrichlorosilane corresponding to the silicon compound 1 of the oxide precursor is 0.3.

### (3-1-2-2) Process for Application to a Substrate and Process for Forming an Oxide Mesostructured Film Having Ordered Structure

Film formation is performed on the silicon substrate prepared in the process (3-1-1) using a spin coating device (Rotation speed of 3000 or 5000 rpm). Thereafter, the substrate is allowed to stand for 24 hours or longer, and then evaluation is performed.

### (3-1-3) Evaluation Process

The XRD pattern is recorded using CuKα rays with X-ray diffraction device (Rigaku ATX-G).

### (3-2) Results

Table 2 shows the list of profiles of the oxide mesostructured film prepared in this example.

TABLE 2

| Atomic number ratio | Half width value of | Lattice plane |
|---|---|---|
| x of silicon | rocking curve of | spacing of out-of- |
| compound 1 | in-plane XRD (/°) | plane XRD (/nm) |
| 0.3 | 45 | 10 |

It is confirmed from Table 2 that a titanium oxide-silicon oxide complex oxide mesostructured film prepared using dodecyltrichlorosilane has an oriented ordered structure. Furthermore, it is confirmed from the two-dimensional XRD pattern and the cross-sectional SEM image that the oxide mesostructured film has a two-dimensional hexagonal structure. Moreover, it is confirmed that the rocking curve profile of the in-plane XRD of the oxide mesostructured film shows the peak in a direction of ±90° to the rubbing direction and the orientation direction of cylindrical structures is a direction perpendicular to the rubbing direction of the substrate.

The following items are confirmed from this example based on the results above.

A. In the manufacturing method according to the invention, the use of n-dodecyltrichlorosilane as the silicon compound 1 allows the formation of the oxide mesostructured film having an in-plane oriented ordered structure.
B. The prepared oxide mesostructured film is an oxide mesostructured film having a structure in which cylindrical structures are packed in the shape of a honeycomb. The orientation direction of the cylindrical structures is a given direction throughout in the film plane.
C. When CuKα rays are used as incident X-rays in the X-ray diffraction measurement in the Bragg-Brentano geometry, the prepared oxide mesostructured film shows the peak of Bragg reflection in the angle region equivalent to the lattice spacing d=10 nm.
D. In the prepared oxide mesostructured film, the number of silicon atoms to which an n-dodecyl group is 0.3 in terms of the atomic number ratio x when the number of atoms of silicon or metallic elements among the elements constituting oxides of the mesostructured film is set to 1.
E. The oxide mesostructured film having the in-plane ordered structure is prepared on the substrate with anisotropic molecular orientation in such a manner as to contact the substrate.
F. The orientation direction of the cylindrical structures of the oxide mesostructured film is perpendicular to the direction showing the anisotropy of the substrate with anisotropic molecular orientation.

### Example 4

This example describes a method for manufacturing a uniaxially oriented silicon oxide mesostructured film using a block copolymer EO(20) PO(70) EO(20) for a surfactant and using tetraethoxysilane, dodecyltriethoxysilane, and hydroxymethyl triethoxysilane as an oxide precursor.

### (4-1) Experiment

(4-1-1) Process for Preparing a Substrate with Anisotropic Molecular Orientation

A substrate with anisotropic molecular orientation was prepared using the same technique as in (1-1-1).

(4-1-2) Process for Forming an Oxide Mesostructured Film Having an Oriented Ordered Structure in the Film Plane by Performing a Polycondensation Reaction of an Oxide Precursor in the Presence of a Surfactant, and then Giving the Same Onto the Substrate

This process is described while dividing the same into the following two processes.

### (4-1-2-1) Process for Preparing a Precursor Solution of an Oxide

As a compound corresponding to the silicon compound 1, n-dodecyltriethoxysilane was used. As a compound corresponding to the silicon compound 2, hydroxymethyl triethoxysilane was used. A precursor solution of a silicon oxide mesostructured film was prepared by adding an ethanol solution of the block copolymer EO(20) PO(70) EO(20) to a solution obtained by mixing ethanol, 0.01 M hydrochloric acid, tetraethoxysilane, n-dodecyltriethoxysilane, and hydroxymethyl triethoxysilane for 15 minutes, and then stirring the mixture for 3 hours. The mixing ratio (molar ratio) is as follows: tetraethoxysilane: (0.7-Z), n-dodecyltriethoxysilane: 0.3, hydroxymethyl triethoxysilane: Z, hydrochloric acid: 0.0011, (water (contained in hydrochloric acid): 6) ethanol: 5.2, and block copolymer: 0.0096-0.0192:ethanol (for dissolution of the block copolymer) 3.5. Z represents the atomic number ratio of silicon contained in the oxide precursor derived from the silicon compound 2 when the number of atoms of silicon constituting the silicon oxide precursor is set to 1 or the atomic number ratio of silicon to which carbon, to which a hydroxyl group is bonded, is bonded when the number of atoms of silicon constituting the silicon oxide mesostructured film is set to 1.

As Example, solutions in which the atomic number ratio z of the silicon compound 2 was set to 0.02, 0.1, and 0.2 were prepared. Separately, solutions in which the atomic number ratio z of the silicon compound 2 was set to 0.01 and 0.3 were prepared as a comparison target.

The solution is diluted as appropriate for use for the purpose of film thickness adjustment.

### (4-1-2-2) Process for Application to the Substrate and Process for Forming an Oxide Mesostructured Film Having an Ordered Structure

Film formation is performed on the silicon substrate prepared in the process (4-1-1) using a spin coating device (Rotation speed of 5000 rpm). Thereafter, the substrate was allowed to stand for 24 hours or longer, and then evaluation was performed.

### (4-1-2-3) Process for Removing a Template

The prepared oxide mesostructured film is immersed in ethanol, and then held at 80° C. for 8 hours to thereby remove the template.

### (4-1-3) Evaluation Process

The XRD pattern is recorded using CuKα rays with an X-ray diffraction device (Rigaku ATX-G). The removal of the template is confirmed by the IR spectrum based on a reduction in the peak at 830 to 880 cm⁻¹ derived from C—CH₃ in the template molecules.

### (4-2) Results

Table 3 shows the half width value of the rocking curve of the in-plane XRD to the value of the atomic number ratio Z of the silicon compound 2 of the silicon oxide mesostructured film prepared in Example 4. It was confirmed from Table 3 that when z is set to 0.02 or more and 0.2 or lower, the oxide mesostructured film has particularly high ordered structure.

On the other hand, the samples in which Z was set to 0.01 and 0.3 did not show a diffraction pattern showing a relatively high orientation.

TABLE 3

| Atomic number ratio Z of | Half width vale of rocking |
|---|---|
| silicon compound 2 | curve of in-plane XRD (/°) |
| 0.02 | 22 |
| 0.1 | 6.5 |
| 0.2 | 18 |
| 0.01 | 32 |
| 0.3 | 35 |

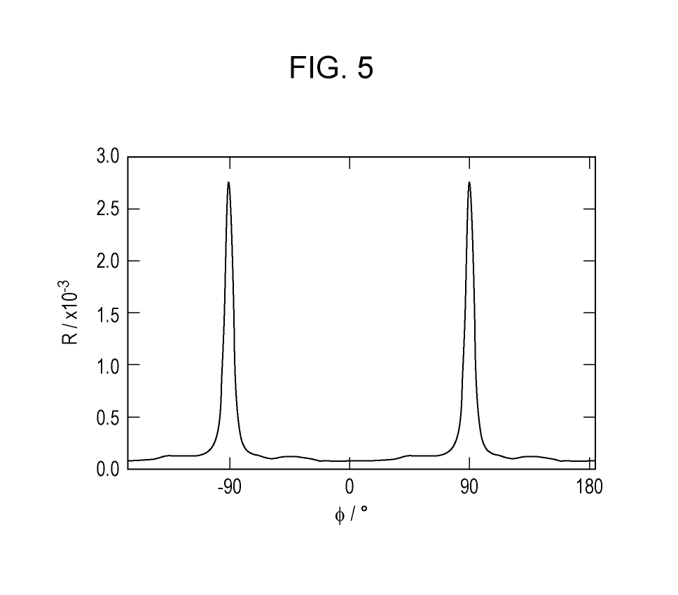

FIG. 5 illustrates the in-plane rocking curve profile of the silicon oxide mesostructured films when the atomic number ratio Z of the silicon compound 2 of the silicon oxide mesostructured films prepared in Example 4 is 0.1. In FIG. 5, the horizontal axis represents the angle φ of the incident X-rays to the rubbing direction and the vertical axis represents the reflectance R of the X-rays. These profiles showed the peak in a direction of ±90° to the rubbing direction.

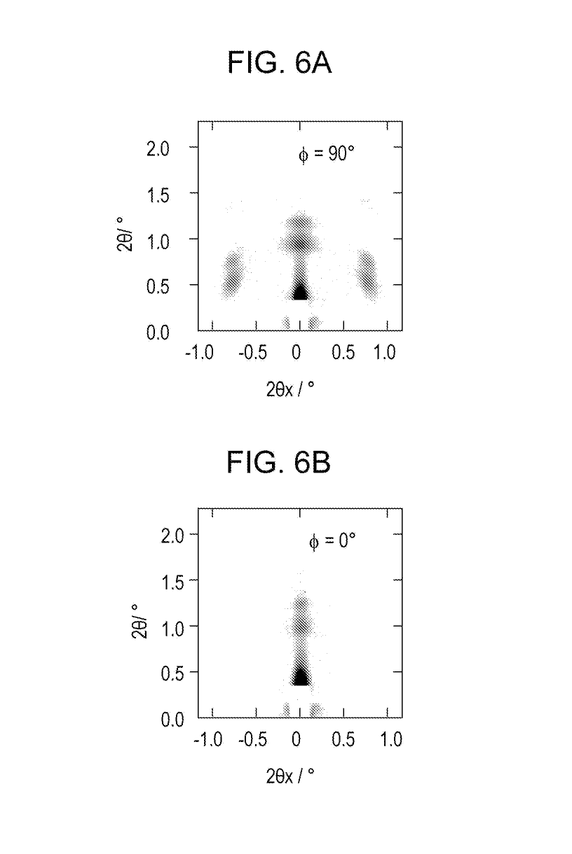

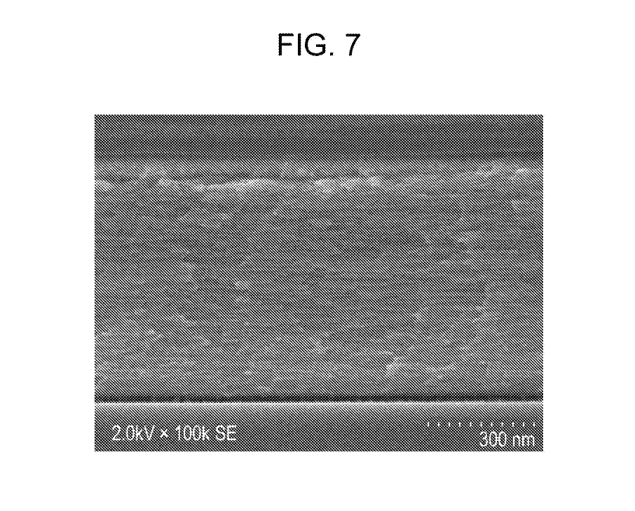

FIGS. 6A and 6B illustrate the two-dimensional XRD pattern when the atomic number ratio Z of the silicon compound 2 of the silicon oxide mesostructured films prepared in Example 4 is 0.1. In FIGS. 6A and 6B, the vertical axis represents the angle of a direction perpendicular to the substrate plane and the horizontal axis represents the angle of the substrate in-plane direction. FIG. 6A illustrates a pattern when the incident direction of X-rays is 90° to the rubbing direction. FIG. 6B illustrates a pattern when the incident direction of X-rays is 0° to the rubbing direction. FIG. 7 illustrates the cross-sectional SEM image when the atomic number ratio Z of the silicon compound 2 of the silicon oxide mesostructured films prepared in Example 4 is 0.1. The cross section shows a cross section at 90° to the rubbing direction. A pattern parallel to the substrate plane at the lower portion of the image is confirmed.

It was confirmed from FIGS. 6A, 6B, and 7 that the silicon oxide mesostructured film is a silicon oxide mesostructured film having a structure (two-dimensional hexagonal structure) such that cylindrical structures are packed in the shape of a honeycomb and the orientation direction of the cylinders is 90° to the rubbing direction.

In the samples of this example, even after the removal of the template, the silicon oxide mesostructured film holds the mesostructure, and the removal of the template is confirmed by the IR spectrum.

The following items are confirmed from this example based on the results above.

A. In the manufacturing method of the invention, due to the fact that the atomic number ratio of silicon contained in the oxide precursors derived from the silicon compound 2 to silicon of all the oxide precursors constituting the silicon oxide precursors is 0.02 or more and 0.2 or lower, the silicon oxide mesostructured films having an in-plane ordered structure having particularly high orientation can be formed.
B. The silicon oxide mesostructured films prepared under the conditions where the atomic number ratio of silicon contained in the oxide precursor derived from the silicon compound 2 is 0.02 or more and 0.2 or lower are oxide mesostructured films having a structure in which cylindrical structures are packed in the shape of a honeycomb. The orientation direction of the cylindrical structures is highly controlled and is a given direction throughout in the film plane.
C. In the prepared silicon oxide mesostructured films having an in-plane oriented ordered structure, when the number of atoms of silicon constituting oxides of the silicon oxide mesostructured films is set to 1, the atomic number ratio of silicon to which carbon, to which a hydroxyl group is directly bonded, is bonded is 0.02 or more and 0.2 or lower.
D. The silicon oxide mesostructured films having the in-plane ordered structure are prepared on the substrate with anisotropic molecular orientation in such a manner as to contact the substrate.
E. The orientation direction of the cylindrical structures of the prepared oxide mesostructured films having the in-plane oriented ordered structure is perpendicular to the direction showing the anisotropy of the substrate with anisotropic molecular orientation.
F. The silicon oxide mesostructured films having the in-plane oriented ordered structure can be formed into mesoporous films.

The oxide mesostructures according to the suitable embodiment of the invention have a structure period having a good orientation on a substrate. By introducing a light emitting material into the oxide mesostructured films according to the suitable embodiments of the invention, for example, the oxide mesostructured films can be formed into polarized light emitting elements. The oxide mesostructures according to the suitable embodiments of the invention are not limited thereto and can be applied to devices utilizing the anisotropy of materials.

According to the suitable embodiments of the invention described above, an oxide mesostructure having a structure period having a good orientation on a substrate and a method for manufacturing the same can be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-016897 filed Jan. 30, 2012, which is hereby incorporated by reference herein in its entirety.

What is claimed is:

1. An oxide mesostructured film, which has a structure in which cylindrical structures are packed in a shape of a honeycomb,
an orientation direction of the cylindrical structures being a given direction throughout in a film plane,
at least one peak appearing in an angle region corresponding to a plane spacing of 8 nm or more in an X-ray diffraction measurement in a Bragg-Brentano geometry, and
a number of atoms (X) of silicon to which an alkyl group having 8 or more carbon atoms is bonded to a number of atoms (Y) of silicon or metallic elements among elements constituting oxides of the oxide mesostructured film being 0.1 or more and 0.5 or lower in terms of an atomic number ratio (X/Y).

2. The oxide mesostructured film according to claim 1, wherein
the oxide contains silica, and
a number of atoms (X″) of silicon to which an alkyl group having 8 or more carbon atoms is bonded to a number of atoms (Y″) of silicon of the silica is 0.1 or more and 0.5 or lower in terms of an atomic number ratio (X″/Y″).

3. The oxide mesostructured film according to claim 1, which is provided on a substrate having anisotropy in an orientation direction of molecules in a substrate plane.

4. The oxide mesostructured film according to claim 1, wherein an orientation direction of the cylindrical structures is perpendicular or almost perpendicular to the orientation direction of the molecules of the substrate.

5. The oxide mesostructured film according to claim 1, wherein the oxide mesostructured film is a mesoporous film.

6. An oxide mesostructured film, which has a structure in which cylindrical structures are packed in the shape of a honeycomb,
an orientation direction of the cylindrical structures being a given direction throughout in a film plane,
a number of atoms (X) of silicon to which an alkyl group having 8 or more carbon atoms is bonded to a number of atoms (Y) of silicon or metallic elements among elements constituting oxides of the oxide mesostructured film being 0.1 or more and 0.5 or lower in terms of an atomic number ratio (X/Y), and
a number of atoms (Z) of silicon to which carbon, to which a hydroxyl group is directly bonded, is bonded to a number of atoms (Y) being 0.02 or more and 0.2 or lower in terms of an atomic number ratio (Z/Y).

7. The oxide mesostructured film according to claim 6, which is provided on a substrate having anisotropy in an orientation direction of molecules in a substrate plane.

8. The oxide mesostructured film according to claim 6, wherein the orientation direction of the cylindrical structures is perpendicular or almost perpendicular to the orientation direction of the molecules of the substrate.

9. The oxide mesostructured film according to claim 6, wherein the oxide mesostructured film is a mesoporous film.

10. The oxide mesostructured film according to claim 6, wherein at least one peak appears in an angle region corresponding to a plane spacing of 8 nm or more in an X-ray diffraction measurement in a Bragg-Brentano geometry.

11. A method for manufacturing an oxide mesostructured film, comprising:
on a substrate having anisotropy in an orientation direction of molecules in a substrate plane, performing a polycondensation reaction of an oxide precursor containing a silicon compound 1 represented by the following general formula (1) in the presence of a surfactant to form an oxide mesostructured film having an oriented ordered structure in a film plane,
a content of silicon (X′) of the silicon compound 1 to a number of atoms (Y′) of silicon or metallic elements among elements constituting the oxide precursor containing the silicon compound 1 being 0.1 or more and 0.5 or lower in terms of an atomic number ratio (X′/Y′), 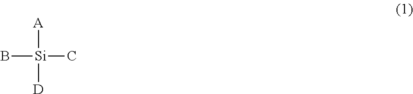
wherein, in formula (1), A represents an alkyl group having 8 or more carbon atoms, B, C, and D represent an alkoxy group, chlorine, bromine, or iodine, and B, C, and D may be the same or may be different from each other.

12. The method for manufacturing an oxide mesostructured film according to claim 11, wherein the oxide precursor further contains a silicon compound 2 represented by the following general formula (2) and a content of silicon (X″) of the silicon compound 2 to a number of atoms of silicon or metallic elements (Y″) among elements constituting the oxide precursor containing the silicon compound 2 is 0.02 or more and 0.2 or lower in terms of an atomic number ratio (X″/Y″), 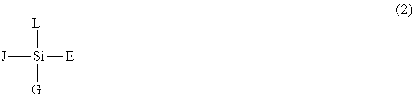
wherein, in formula (2), L represents a carbon atom to which a hydroxyl group is directly bonded, E, G, and J represent an alkoxy group, chlorine, bromine, or iodine, and E, G, and J may be the same or may be different from each other.

13. The method for manufacturing an oxide mesostructured film according to claim 11, comprising:
starting the polycondensation reaction of the oxide precursor in the presence of a surfactant, and
after the process, giving the oxide precursor and the surfactant onto the substrate,
wherein the formation of the oxide mesostructured film on the substrate is performed after these processes.
